(19) United States
(12) Patent Application Publication
(10) Pub. No.: US 2009/0073746 A1
(43) Pub. Date: Mar. 19, 2009

(54) STATIC RANDOM ACCESS MEMORY CELL

(75) Inventors: Ranick K.M. Ng, Leuven (BE); Gerben Doornbos, Heverlee (BE); Radu Surdeanu, Roosbeek (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/297,299

(22) PCT Filed: Apr. 19, 2007
(86) PCT No.: PCT/IB2007/051415

§ 371 Date: Oct. 15, 2008

(30) Foreign Application Priority Data
Apr. 24, 2006 (EP) 06113004.3

(51) Int. Cl. G11C 11/412; H01L 27/11

(52) U.S. Cl. 365/154; 257/365; 257/E27.099

(57) ABSTRACT

A static random access memory means is provided. The SRAM memory means comprises a first pass-gate FET (T6) which is coupled between a first node (A) and a bitline-bar (BLB). A second pass-gate FET (T1) is coupled between a second node (B) and a bitline (BL). The second node (B) is coupled to the first pass-gate FET (T6) and the first pass-gate FET (T6) is switched according to the voltage (V_{B}) at the second node (B). The first node (A) is coupled to the second pass-gate FET (T1). The second pass-gate FET (T1) is switched according to the voltage (V_{A}) on the first node (A).

The present invention relates to a static random access memory means and an integrated circuit.

Static Random Access Memories (SRAM) are widely used, either stand-alone as e.g. fast cache memory or embedded in CPUs. An SRAM cell typically consists of a bi-stable flip-flop connected to the internal circuitry by access transistors, i.e. the pass transistors or the pass gates. If a given cell is not addressed, its pass gates are closed and the data is kept in a stable state latched within the flip-flop. The SRAM cell can be operated in three different modes, namely a static mode, a write mode and a read mode.

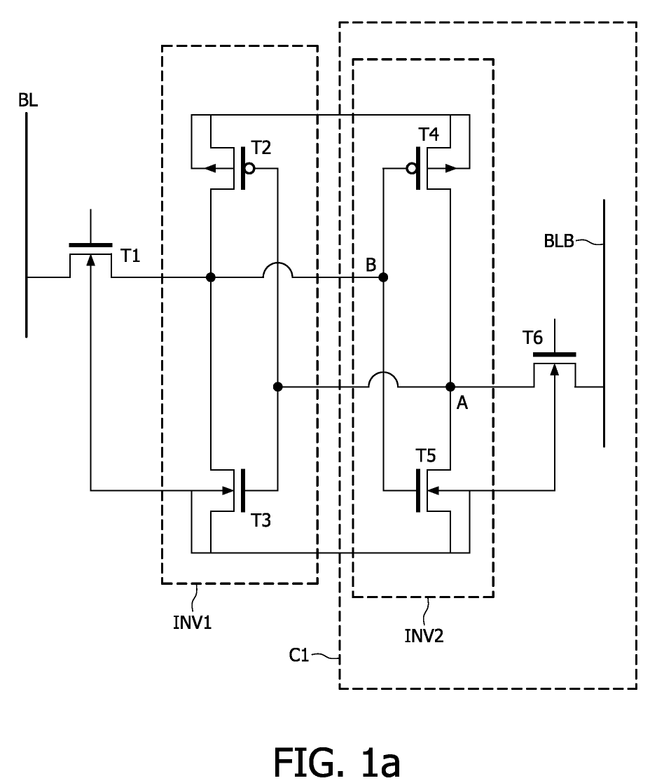

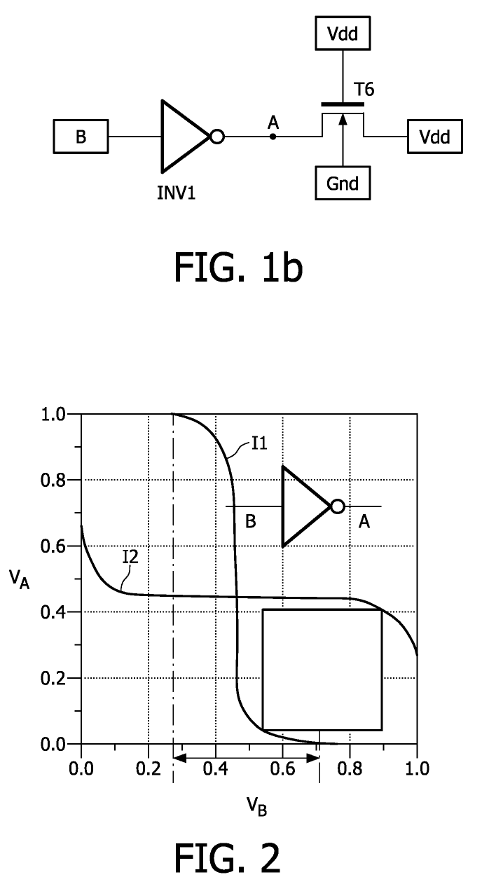

FIG. 1a shows a circuit diagram of a typical 6-transistor (6T) SRAM cell according to the prior art. Here, the SRAM cell comprises 6 transistors T1-T6. A first pull-up transistor T2 is coupled between power supply line Vdd and node B. A first pull-down transistor T3 is coupled between node B and ground line Vss. A second pull-up transistor T4 is coupled between power supply line Vdd and node A. A second pull-down transistor T5 is coupled between node A and ground line Vss. Node B is connected to the bit line BL by a first pass-gate transistor T1. Node A is connected to the bit line-bar BLB by a second pass-gate transistor T6. Typically, T1, T3, T5 and T6 are n-channel MOSFETs with their body contact connected to Vss. T2 and T4 are p-channel MOSFETs with their body contact connected to Vdd. T4 and T5. Transistors T4 and T5 constitute a first inverter INV1 with node B as input and node A as output. Transistors T2 and T3 constitute a second inverter INV2 with node A as input and node B as output. The SRAM cell can be in two static states: (i) potential of node A close or equal to Vdd (“1”) and potential of node B close or equal to Vss (“0”), and (ii) potential of node A close or equal to Vss (“0”) and potential of node B close or equal to Vdd (“1”). The inverter INV1 together with pass-gate transistor T6 constitute sub-circuit C1.

In the static mode of the SRAM cell, the gates of its pass-gates are biased such that the pass gates are closed. In the write mode, a “1” must be written on node B and a “0” must be written on node A or vice versa. The bitline and bitline-bar are biased accordingly, and the pass gates are opened. In the read mode, the bitlines are pre-charged to “1”. Thereafter, the pass gates are opened and one of the two bitlines will be slightly discharged. The voltage difference between bitline and bitline-bar is evaluated by a sensed amplifier. In the static mode and in the read mode, the SRAM cell must keep its state independent of a noise event. In the read mode, the static noise margin SNM (the largest square in the butterfly curve) is reduced because the inverter is resistively loaded by the open pass gate.

FIG. 1b shows a block diagram of part C1 of the cell of FIG. 1a during a read-out. The first inverter INV1 is coupled between the node B and the node A. The gate and the drain of the sixth transistor T6, i.e. the passgate, are coupled to the supply voltage Vdd. The body contact of the passgate is coupled to ground GND.

FIG. 2 shows a graph I1 of the voltage on the output node A of inverter INV1 as function of its input voltage on node B. A graph I2 shows the voltage on output node B of INV2 as function of its input voltage on node A. In case of equal inverters, the two graphs can be mirrored into each other. Graph I1 and I2 constitute a so-called butterfly curve. The length of the largest square that can be drawn in a wing of the butterfly curve, as indicated in FIG. 2, represents the static noise margin (SNM) A noise event that triggers a potential change on one of the nodes larger than the SNM can lead to an undesired change of memorized state.

The back-to-back inverters INV1, INV2 are coupled to the bitline BL and the bitlinebar BLB via passgate MOSFETs such that the data stored at the nodes A and B can be read out, or data can be written to nodes A and B. To initiate the read out, the bitlines BL and BLB are precharged to Vdd and the passgates are opened. Therefore, one of the inverters of the cell is loaded resistively by the open passgate. Accordingly, the characteristics of the inverter is distorted such that the static noise margin SNM is reduced.

In “FinFET-Based SRAM Design” by Zheng Guo, in International Symposium on low power electronics design ISLPED 2005, a SRAM cell is composed of FinFET transistors. In particular, multi-gate FinFET comprises a front gate and a second gate. The second gate of the pass-gate FinFET is coupled to the same node as its drain terminal. Accordingly, the static noise margin of this circuit will depend on the read current of the circuit.

It is an object of the invention to provide a static random access memory means, enabling an improved data retention capability without distorting the static noise margin of the circuit.

This object is solved by a static random access memory means according to claim 1 and by an integrated circuit according to claim 7.

Therefore, a static random access memory means is provided. The SRAM memory means comprises a first pass-gate FET which is coupled between a first node and a bitline-bar. A second pass-gate FET is coupled between a second node and a bitline. The second node is coupled to the first pass-gate FET and the first pass-gate FET is turned on according to the voltage at the second node. The first node is coupled to the second pass-gate FET. The second pass-gate FET is turned on/off according to the voltage on the first node. Accordingly, the pass-gate can be turned on independently.

According to an aspect of the present invention, a first and second inverter is coupled between the first and second node, respectively.

According to a preferred aspect of the invention, the first and second pass-gate FET each comprises a front gate and a back gate. The back gate of the first pass-gate FET is coupled to the second node, and the back gate of the second pass-gate FET is coupled to the first node. Therefore, by controlling the back gates of the first and second pass-gate FET, the pass-gates can be switched on or off.

According to still a further aspect of the invention, the first and second pass-gate each comprises a body terminal. The body terminal of the first pass-gage is coupled to the second node, and the body terminal of the second pass-gate is coupled to the first node.

According to a preferred aspect of the invention, the first and second pass-gate FET are each implemented as a multi-gate field effect transistor with separate gates.

The invention also relates to an integrated circuit which comprises a static random access memory means. The SRAM memory means in turn comprises a first pass-gate FET which is coupled between a first node and a bitline-bar. A second pass-gate FET is coupled between a second node and a bitline. The second node is coupled to the first pass-gate FET and the first pass-gate FET is turned on according to the voltage at the second node. The first node is coupled to the second pass-gate FET. The second pass-gate FET is turned on according to the voltage on the first node.

The invention relates to the idea to provide an independent switching means for turning on/off pass-gates. A switching means can be arranged in series with the pass-gate such that the current path via the pass-gate is switched off when the output voltage of the further inverter of the SRAM cell is less than a predetermined value. Such a switching means can be implemented by a pass-gate if the pass-gate comprises at least a first and second control gate. The first control gate can be controlled by the address decoder of the memory. The second gate can be controlled by the output voltage of the further inverter. One implementation of such a switching means is a multi-gate field effect transistor. Furthermore, the pass-gates can be implemented by symmetrical FinFET without any additional area penalty.

Other aspects of the invention are defined in the dependent claims.

The invention as well as the embodiments thereof will now be elucidated in more detail with reference to the drawings.

FIG. 1a shows a circuit diagram of a 6T SRAM cell according to the prior art;

FIG. 1b shows a block diagram of part C1 of the cell of FIG. 1a during a read-out;

FIG. 2 shows a graph of the voltage at the output node A in a circuit of FIG. 1a;

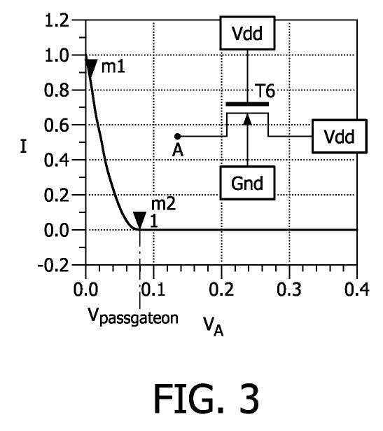

FIG. 3 shows a graph of the voltage at node A and the passgate current during a read-out;

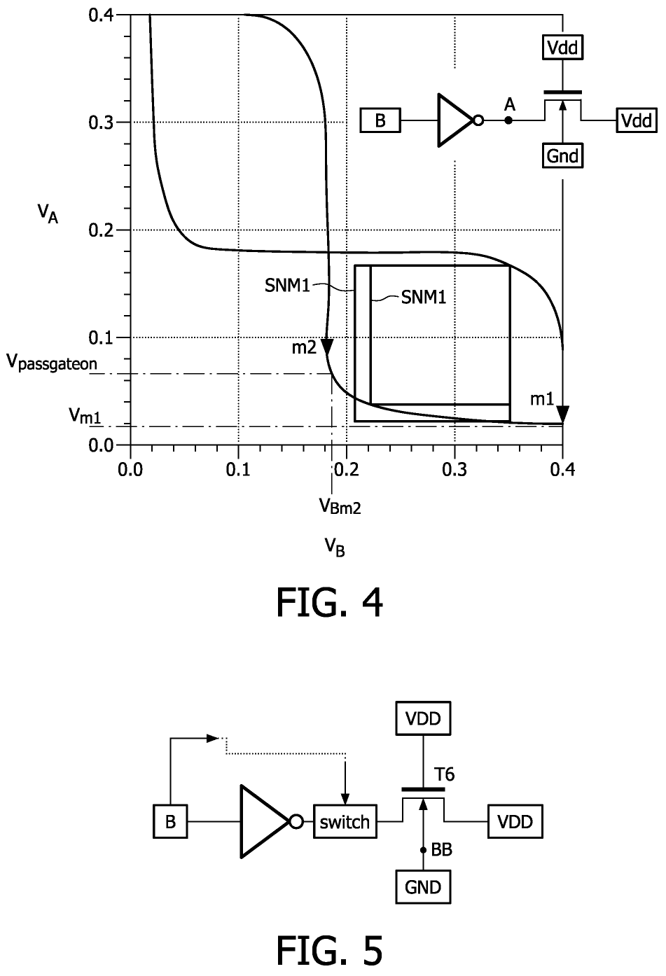

FIG. 4 shows a graph of the voltage of the output node A in a circuit of FIG. 3;

FIG. 5 shows a block diagram of a circuit diagram of a part of a SRAM cell according to a first embodiment during read-out;

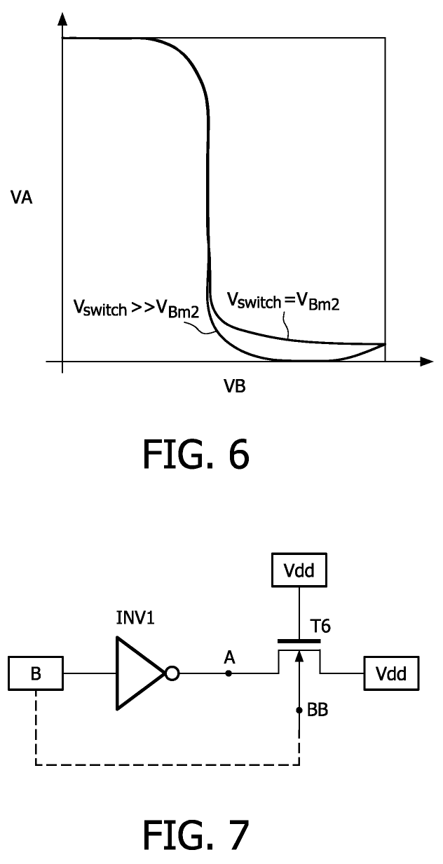

FIG. 6 shows a graph of voltages at nodes A and B during switching according to the first embodiment;

FIG. 7 shows a circuit diagram of part of the SRAM cell during read-out according to a second embodiment;

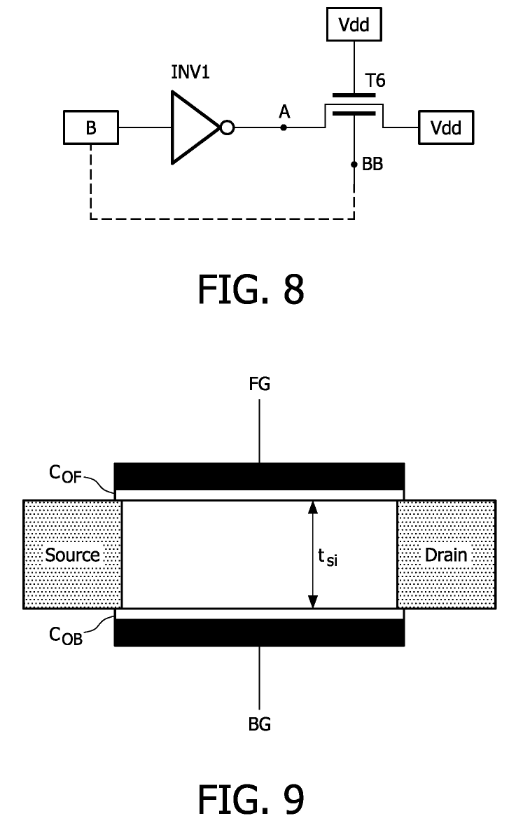

FIG. 8 shows a circuit diagram of part of the SRAM cell according to a third embodiment;

FIG. 9 shows a basic representation of a FinFET as used in the SRAM cell according to FIG. 8;

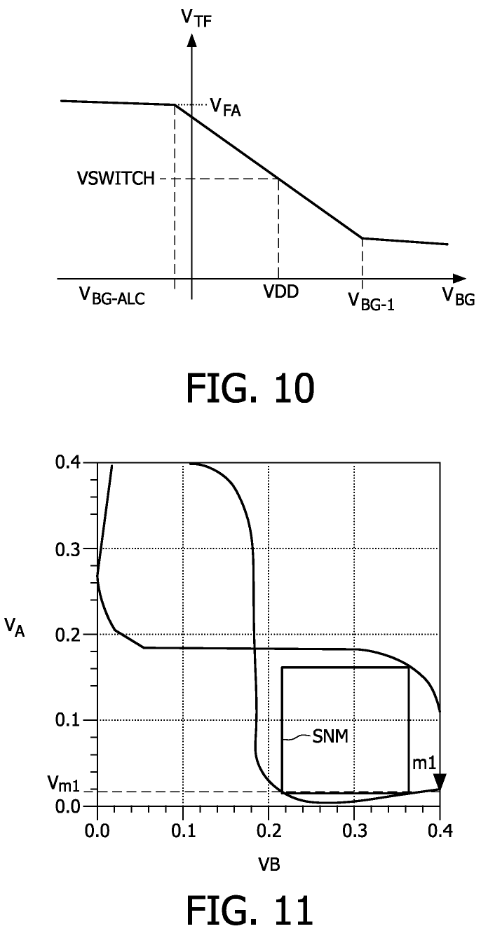

FIG. 10 shows a graph of the relation of a switch voltage and a back-gate voltage of a FET according to FIG. 8;

FIG. 11 shows a graph of voltages at nodes A and B during read-out according to the third embodiment;

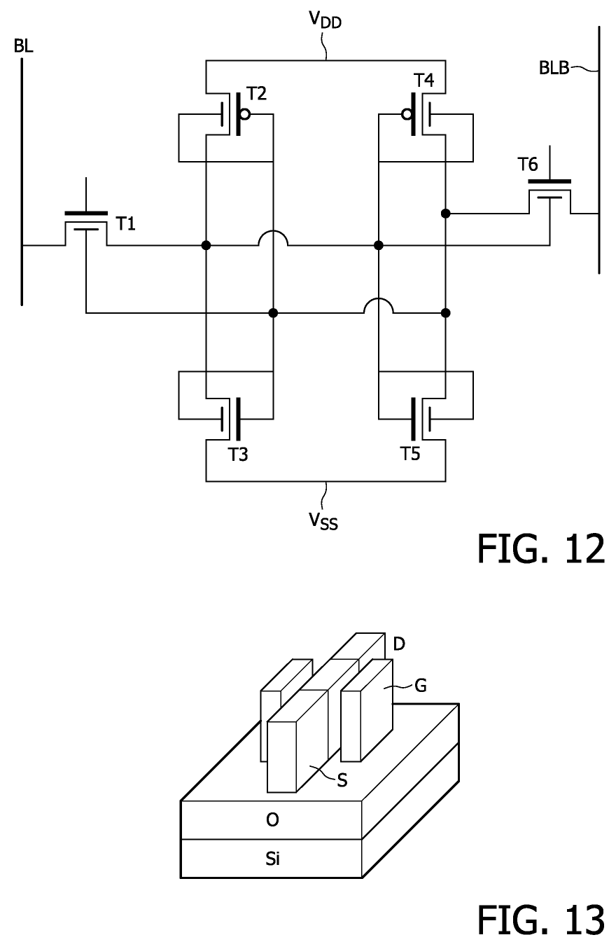

FIG. 12 shows a circuit diagram of a memory cell according to the fourth embodiment;

FIG. 13 shows a basic representation of a Fin FET according to the fifth embodiment;

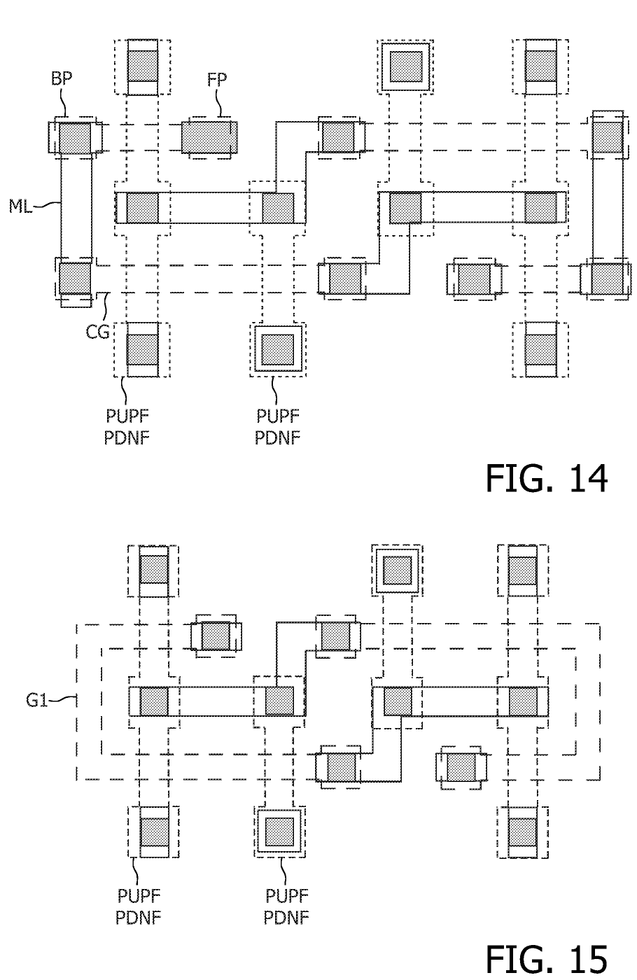

FIG. 14 shows a possible implementation of a SRAM cell according to the sixth embodiment; and

FIG. 15 shows a representation of an alternative implementation of the circuit diagram of FIG. 12.

FIG. 3 shows a graph of the voltage at node A and the passgate current during read-out, and a block diagram of sub-circuit C1. The gate of the passgate is coupled to the supply voltage Vdd, its drain is coupled to Vdd and its body terminal is coupled to ground Vss. If the passgate is biased accordingly, an increase of the voltage at the node A will lead to a drop of the current source via the MOSFET. The current source is turned off at a voltage of V_{passgateon} or V_{PGNon}. This is depicted by the marker m1.

FIG. 4 shows graph of the voltage at node A. Here, the inverter characteristics during read-out, of the sub-circuit C1 indicated in the inset, with node B high “1” and node A low “0” are depicted. Graph I2 in FIG. 4 is the mirror image of graph I1. Because the pass-gate is open during read-out, it sinks current from node A to the bit line bar, and the potential on node A is raised to Vm1>0. Hence, the inverter characteristics are distorted with respect to FIG. 2, with the wings of the butterfly not touching the VA=0 and VB=0 axes. The smallest square in the butterfly is therefore reduced in size, and accordingly is the static noise margin.

The static noise margin, indicated by the largest square, is reduced w.r.t. the static-state case due to the inverter being loaded by the opened pass-gate.

FIG. 5 shows a block diagram of a circuit diagram of a part of a SRAM cell during read-out according to a first embodiment. The circuit diagram according to the first embodiment substantially corresponds to the circuit diagram according to FIG. 1b, wherein an additional switch S is coupled between the first inverter INV1 and the passgate T6. The gate of the passgate is biased to Vdd, the drain is biased to Vdd and the body terminal is biased to gnd. The voltage V_{B} at node B is used to toggle switch S. The switch S is switched on, if the voltage V_{B}>Vs or V_{switch}. Accordingly, by providing a switch between the inverter and the passgate, an independent setting (independently from the voltage at the node A) of the voltage for turning on the passgate can be provided. Hence, by only triggering the switch S at a voltage being greater the e.g. V_{Bm2} (V_{Bm2} corresponds to the threshold of the switch S) according to FIG. 4, the undistorted characteristics of the inverter can be preserved.

The voltage to toggle the switch can be sensed at the node B. If the voltage Vₛ of the switch S equals the voltage V_{Bm2} such a case would correspond to the situation according to FIG. 4. However, if the toggle voltage >>V_{Bm2} the undistorted inverter characteristics are maintained until V_{B}, i.e. the voltage at node B>V_{S}.

FIG. 6 shows a graph of voltages at nodes A and B during read-out according to a first embodiment. Here, two different curves are depicted. The upper curve corresponds to the case where the toggle voltage of the switch S equals V_{Bm2}. The lower curve corresponds to the case where the toggle voltage of the switch S>>V_{Bm2}.

FIG. 7 shows a circuit diagram of part of the SRAM cell during read-out according to a second embodiment. Here, the electrical switching characteristics of the MOSFET is controlled by applying a bias voltage (instead of Vss) to the body contact BB, wherein the bias voltage may correspond to the voltage V_{B} at the node B. In FIG. 7 a bulk CMOS implementation is depicted, where the voltage on node B is coupled to the body contact BB of the MOSFET. Preferably, from layout point of view, the bodies of all of the NMOS transistors are coupled so that it can become difficult to implement the circuit of FIG. 7.

FIG. 8 shows a circuit diagram of part of the SRAM cell during read-out according to a third embodiment. The circuit diagram according to FIG. 8 substantially corresponds to the circuit diagram of FIG. 7. However, FIG. 8 depicts a multi-gate (MUGFET) implementation with separate gate connections where the node BB is attached to the backgate of the MUGFET. The MUGFET can be a planar dual-gate transistor or a FinFET.

A FinFET transistor constitutes a multi-gate MOSFET transistor, typically built on a SOI substrate. The gate is placed on two, three, or four sides of the channel or wrapped around the channel, such that a multi-gate structure is formed. The FinFET devices have significantly faster switching times and higher current density than the mainstream bulk CMOS technology and allow the provision of independent backgate potentials for individual transistors.

FIG. 9 shows a basic representation of a FinFET as used in the SRAM cell according to FIG. 8. Here, the FET transistor comprises a source, a drain and a front gate FG and a back-gate BG with an oxide there between. Accordingly, a capacitance C_{OF} (oxide-front) is present at the front gate FG and a capacitance C_{OB} (oxide-back) is present at the back-gate BG.

FIG. 10 shows a graph of the relation of a switch voltage and a back-gate voltage of a FET according to FIG. 8.

The threshold voltage V_{TF} of the front gate for a fully depleted SOI and multi gate FinFET corresponds to:

$${V}_{TF} \approx {V}_{FA} - \frac{{C}_{b} {C}_{OB}}{{C}_{OF} ( {C}_{b} + {C}_{OB} + {C}_{sb} )} ( {V}_{BG} - {V}_{BG - ACC} ) ,$$

wherein V_{FA} corresponds to the front accumulation voltage, C_{OB} corresponds to the capacitance of the back-gate, C_{OF} corresponds to the capacitance of the front gate, V_{BG} corresponds to the voltage of the back-gate, and V_{BG-ACC} corresponds to the voltage of the back-gate.

The threshold voltage V_{TF} should be selected such that it corresponds to the toggle voltage or the switch voltage V_{S}, when the back-gate voltage V_{BG} corresponds to Vdd.

Moreover, the back-gate should not invert if its voltage V_{BG} approaches Vdd, i.e. the FET should comprise an asymmetrical front and back-gate characteristics.

FIG. 11 shows a graph of the inverter characteristics of the fourth embodiment depicted in FIG. 8 during read-out. Here, the square of the SMN is depicted in the lower right hand corner. Accordingly, an undistorted inverter characteristics is achieved until V_{B} at node B>V_{S}.

The graph of the voltage V_{A} at node A is depicted for an asymmetrical MUGFET implementation of the passgate according to FIGS. 8 and 12. The resulting square for the SNM fitting into the butterfly curve corresponds to the square as obtained for a memory cell without a read access according to FIG. 2. The voltage in a stored state as the marker m1 according to FIG. 11 corresponds to those of FIG. 4, i.e. both cases correspond to each other with regard to the read current, the drive strength and/or the speed of the SRAM cell.

FIG. 12 shows a circuit diagram of a memory cell according to the fourth embodiment. As the circuit diagram according to FIG. 1a, the cell comprises six transistors T1-T6. The most striking difference of the circuit diagram according to FIG. 12 as compared to the circuit diagram according to FIG. 1a is that the body terminal or the back-gate of transistor T6 is coupled to node B, and the body terminal/back gate of T1 is coupled to node A. In other words, a back-gate feedback is applied on the passgates. Apart from the asymmetrical passgates, all other FET have symmetrical front and back characteristics (pull up PUP T2 and T4; pull down PDN T3 and T5).

FIG. 13 shows a basic representation of a FinFET according to the fifth embodiment. The FinFET is implemented with independent gates G fabricated on SOI. In particular, this passgate is implemented as a FinFET with an asymmetrical front and back gate behaviour.

FIG. 14 shows a possible implementation of a SRAM cell according to the sixth embodiment. Here, an implementation of the circuit diagram of FIG. 12 is shown. A connection is provided between the back-gates of the passgate and the gate of one of the inverter pairs by means of a metal layer ML. Here, the back BP of the pass-gate and the front FP of the pass-gate is shown. The metal layer ML is depicted as solid lines. Furthermore, the pull up and the pull down Fin_FET PUPF, PDNF is also depicted. Furthermore, a common gate CG is shown for the pull down and pull up field effect transistor. This common gate can also be implemented as a gate of one of the inverters of the SRAM.

FIG. 15 shows a representation of an alternative implementation of the circuit diagram of FIG. 12. The back-gate of the passgate and the pull down and pull up FET T2, T3 share a common gate which is implemented as a single continuous gate G1.

Although in the above embodiments, a six-transistor SRAM cell has been described, the basic principles of the invention can also be applied to other types of SRAM with the two pass gates coupled to the bitline and the bitline-bar.

Accordingly, a SRAM cell is provided which is able to maintain a high SNM with sufficient read current. This is achieved by a state dependent body feedback mechanism of the passgate of the memory cell.

It should be noted that although the above memory cell has been described in six transistors, the basic principles of the invention are also applicable to a memory cell with four transistors.

The invention relates to the idea to provide a switch in series with a pass-gate of the cell. The switch will switch off the current path via the passgate if the output voltage of the inverter of the SRAM cell is less than a predetermined switch value. The switch may be implemented by the passgate wherein the passgate has a first and second control gate. The first control gate can be controlled by the address decoder of the memory cell while the second gate can be controlled by the output voltage of the second inverter of the memory cell. Preferably, the second gate is formed by the body of the passgate. The switch can be implemented by a multi gate FET (MUGFET). More preferably, the switch is implemented as an asymmetrical Fin FET.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

Furthermore, any reference signs in the claims shall not be constrained as limiting the scope of the claims.

1. Static random access memory means, comprising
a first pass-gate FET coupled between a first node and a bitline-bar,
a second pass-gate FET coupled between a second node and a bitline,
wherein the second node is coupled to the first pass-gate FET and the first pass-gate FET is switched according to a voltage at the second node,
wherein the first node is coupled to the second pass-gate FET, wherein the second pass-gate FET is switched according to the voltage at the first node.

2. Static random access memory means according to claim 1, wherein a first and second inverter is coupled between the first and second node.

3. Static random access memory means according to claim 1, wherein the first and second pass-gate FET each comprises a front gate and a back gate, wherein the back gate of the first pass-gate FET is coupled to the second node, wherein the back gate of the second pass-gate FET is coupled to the first node.

4. Static random access memory means according to claim 1, wherein the first and second pass-gate FET each comprises a body terminal, wherein the body terminal of the first pass-gate FET is coupled to the second node, wherein the body terminal of the second pass-gate FET is coupled to the first node.

5. Static random access memory means according to claim 1, wherein the first and second pass-gate FET are implemented as multi-gate field effect transistors with separate gates.

6. Static random access memory means according to claim 1, wherein the first and second pass-gate FET are implemented as FinFET with separate gates.

7. Integrated circuit, comprising a static random access memory having a first pass-gate FET coupled between a first node and a bitline-bar,
a second pass-gate FET coupled between a second node and a bitline,
wherein the second node is coupled to the first pass-gate FET and the first pass-gate FET is switched according to a voltage at the second node, wherein
the first node is coupled to the second pass-gate FET, and wherein the second pass-gate FET is switched according to the voltage at the first node.
